(19) United States
(12) Patent Application Publication
(10) Pub. No.: US 2026/0022446 A1
(43) Pub. Date: Jan. 22, 2026

(54) ALIGNMENT APPARATUS, SUBSTRATE PROCESSING APPARATUS INCLUDING THE SAME, AND ELECTRONIC APPARATUS

(71) Applicants: Samsung Display Co., LTD., Yongin-si (KR); ULVAC, INC., Chigasaki-shi (JP)

(72) Inventors: KYUNGHOON CHUNG, Yongin-si (KR); MASAO NISHIGUCHI, Chigasaki-shi (JP); SHUJI SHIMIZU, Chigasaki-shi (JP); HIRONORI WAKAMATSU, Chigasaki-shi (JP); DAISUKE IWASE, Chigasaki-shi (JP); KAZUHIKO KOIZUMI, Chigasaki-shi (JP); JUNGSEOB LEE, Yongin-si (KR); YONGSIC JEON, Yongin-si (KR); HYEONSIK KIM, Yongin-si (KR); YONG YEO, Yongin-si (KR)

(21) Appl. No.: 19/085,843

(22) Filed: Mar. 20, 2025

(30) Foreign Application Priority Data
Jul. 16, 2024 (KR) 10-2024-0093787

(51) Int. Cl. C23C 14/04

(52) U.S. Cl. CPC C23C 14/042

(57) ABSTRACT

An alignment apparatus according to the embodiments includes a plate, first to fourth connectors, first to third supports, a first driver, and a first holder. The first holder is configured to hold a tray on which a substrate is accommodated. The alignment apparatus may adjust a position and an angle of the tray in six degrees of freedom to more precisely align a mask and the substrate with each other.

### CROSS-REFERENCE TO RELATED APPLICATION(S)

The present application claims priority to and the benefit of Korean Patent Application No. 10-2024-0093787, filed on Jul. 16, 2024, the entire disclosure of which is hereby incorporated by reference.

### BACKGROUND

### 1. Field

One or more aspects of embodiments of the present disclosure are directed toward an alignment apparatus, a substrate processing apparatus including the alignment apparatus, and an electronic apparatus. One or more aspects of embodiments of the present disclosure are directed toward an alignment apparatus used in manufacturing a display device, a substrate processing apparatus including the alignment apparatus, and an electronic apparatus including the display device.

### 2. Description of the Related Art

Flat panel display devices may have superior characteristics compared to cathode ray tube display devices due to their lightweight and relatively thin nature. Representative examples of such flat panel display devices include liquid crystal display devices and organic light emitting diode display devices.

The display device may include a substrate and one or more thin films on the substrate. The thin films may be patterned using a deposition mask to define a plurality of slits within a chamber of a deposition facility. For accurate or suitable patterning of the thin films, precise (e.g., as precise as possible) alignment of the substrate and the deposition mask is desired or required.

### SUMMARY

One or more aspects of embodiments of the present disclosure provide an alignment apparatus capable of precisely or suitably aligning a tray on which a substrate is accommodated.

One or more aspects of embodiments of the present disclosure also provide a substrate processing apparatus capable of precisely or suitably aligning a tray on which a substrate is accommodated.

One or more aspects of embodiments of the present disclosure are directed toward an alignment apparatus used in manufacturing a display device, and an electronic apparatus including the display device.

Additional aspects and features of the disclosures will be set forth in the description which follows, and in part will be apparent from the description, or may be learned by practice of the disclosures.

An alignment apparatus according to one or more embodiments includes a plate including first to fourth sides, first to fourth connectors, first to third supports, a first driver, and a first holder. The first and second sides of the plate each extend in an X-axis direction and are opposite to each other, and the third and fourth sides of the plate each extend in a Y-axis direction and are opposite to each other. The first connector and the second connector are spaced and/or apart (e.g., spaced apart or separated) from each other in the X-axis direction, and each of the first connector and the second connector is fixedly coupled to the first side of the plate. The third connector and the fourth connector are spaced and/or apart (e.g., spaced apart or separated) from each other in the X-axis direction, and each of the third connector and the fourth connector is fixedly coupled to the second side of the plate. The first support extends in the X-axis direction and includes a first end portion and a second end portion, the first end portion of the first support is coupled to the first connector, and the second end portion of the first support is coupled to the second connector. The second support extends in the X-axis direction and includes a first end portion and a second end portion, the first end portion of the second support is coupled to the third connector, and the second end portion of the second support is coupled to the fourth connector. The third support extends in the Y-axis direction, is adjacent to the third side of the plate, and includes a first end portion and a second end portion, and the first end portion of the third support is coupled to the first end portion of the first support. The first driver is arranged between the first end portion of the first support and the first end portion of the third support. The first driver movably and rotatably couples the first end portion of the third support to the first end portion of the first support, such that the first end portion of the third support is movable in the Y-axis direction and a Z-axis direction and rotatable about the X-axis direction. The first holder is fixedly coupled to the third support and is configured to hold a tray on which a substrate is accommodated.

In one or more embodiments, the first driver may include a first-first linear guide extending in the Z-axis direction, a first-second linear guide extending in the Y-axis direction, a first-first moving block slidably coupled to the first-first linear guide, and a first-second moving block slidably coupled to the first-second linear guide and fixedly coupled to the first-first moving block. The first-first moving block may be slidable in the Z-axis direction. The first-second moving block may be slidable in the Y-axis direction.

In one or more embodiments, the first-first moving block may define a first accommodating groove adjacent to the first-first linear guide and having a cylindrical shape extending in the Z-axis direction. A plurality of balls may be arranged in the first accommodating groove.

In one or more embodiments, the first-second moving block may define a second accommodating groove adjacent to the first-second linear guide and having a cylindrical shape extending in the Y-axis direction. A plurality of balls may be arranged in the second accommodating groove.

In one or more embodiments, the first driver may further include a first motor to slide the first-first moving block in the Z-axis direction.

In one or more embodiments, the first-first linear guide may be fixedly coupled to a side surface of the first end portion of the first support opposite to (e.g., facing) the first end portion of the third support.

In one or more embodiments, the first-second linear guide may be rotatably coupled to the first end portion of the third support, such that the first-second linear guide may be rotatable about the X-axis direction.

In one or more embodiments, the alignment apparatus may further include a second driver arranged between the first end portion of the first support and the first connector. The second driver may movably and rotatably couple the first end portion of the first support to the first connector, such that the first end portion of the first support may be movable in the X-axis direction and the Z-axis direction and rotatable about the Y-axis direction.

In one or more embodiments, the second driver may include a second-first linear guide extending in the Z-axis direction, a second-second linear guide extending in the X-axis direction, a second-first moving block slidably coupled to the second-first linear guide, and a second-second moving block slidably coupled to the second-second linear guide and fixedly coupled to the second-first moving block. The second-first moving block may be slidable in the Z-axis direction. The second-second moving block may be slidable in the X-axis direction.

In one or more embodiments, the first driver may further include a second-first motor to slide the second-first moving block in the Z-axis direction, and a second-second motor to slide the second-second moving block in the X-axis direction.

In one or more embodiments, the second-first linear guide may be fixedly coupled to a surface of the first connector opposite to (e.g., facing) the first end portion of the first support.

In one or more embodiments, the second-second linear guide may be rotatably coupled to the first end portion of the first support, such that the second-second linear guide may be rotatable about the Y-axis direction.

In one or more embodiments, the second end portion of the third support may be rotatably coupled to the first end portion of the second support, such that the second end portion of the third support is rotatable about the X-axis direction.

In one or more embodiments, the alignment apparatus may further include a fourth support extending in the Y-axis direction, adjacent to the fourth side of the plate, and including a first end portion and a second end portion, and a second holder fixedly coupled to the fourth support and configured to hold the tray. The first end portion of the fourth support may be coupled to the second end portion of the first support.

In one or more embodiments, the alignment apparatus may further include a third driver arranged between the second end portion of the first support and the second connector. The third driver may movably and rotatably couple the second end portion of the first support to the second connector, such that the second end portion of the first support may be movable in the X-axis direction and the Z-axis direction and rotatable about the Y-axis direction.

In one or more embodiments, the second end portion of the fourth support may be rotatably coupled to the second end portion of the second support, such that the second end portion of the fourth support may be rotatable about the X-axis direction.

A substrate processing apparatus according to one or more embodiments includes a mask frame on which a mask is configured to be accommodated, a tray arranged on the mask frame and on which a substrate is configured to be accommodated, an alignment apparatus arranged on the tray and configured to hold the tray, and a stage arranged on the alignment apparatus. The alignment apparatus includes a plate including first to fourth sides and movably coupled to the stage, first to fourth connectors, first to third supports, a first driver, and a first holder. The first and second sides of the plate each extend in an X-axis direction and are opposite to each other, and the third and fourth sides of the plate each extend in a Y-axis direction and are opposite to each other. The plate is movable in the X-axis direction and the Y-axis direction. The first connector and the second connector are spaced and/or apart (e.g., spaced apart or separated) from each other in the X-axis direction, and each of the first connector and the second connector is fixedly coupled to the first side of the plate. The third connector and the fourth connector are spaced and/or apart (e.g., spaced apart or separated) from each other in the X-axis direction, and each of the third connector and the fourth connector is fixedly coupled to the second side of the plate. The first support extends in the X-axis direction and includes a first end portion and a second end portion, the first end portion of the first support is coupled to the first connector, and the second end portion of the first support is coupled to the second connector. The second support extends in the X-axis direction and includes a first end portion and a second end portion, the first end portion of the second support is coupled to the third connector, and the second end portion of the second support is coupled to the fourth connector. The third support extends in the Y-axis direction, is adjacent to the third side of the plate, and includes a first end portion and a second end portion, and the first end portion of the third support is coupled to the first end portion of the first support. The first driver is arranged between the first end portion of the first support and the first end portion of the third support. The first driver movably and rotatably couples the first end portion of the third support to the first end portion of the first support, such that the first end portion of the third support is movable in the Y-axis direction and a Z-axis direction and rotatable about the X-axis direction. The first holder is fixedly coupled to the third support and is configured to hold the tray.

In one or more embodiments, the alignment apparatus may further include a second driver arranged between the first end portion of the first support and the first connector. The second driver may movably and rotatably couple the first end portion of the first support to the first connector, such that the first end portion of the first support may be movable in the X-axis direction and the Z-axis direction and rotatable about the Y-axis direction.

In one or more embodiments, the alignment apparatus may further include a fourth support extending in the Y-axis direction, adjacent to the fourth side of the plate, and including a first end portion and a second end portion, and a second holder fixedly coupled to the fourth support and configured to hold the tray. The first end portion of the fourth support may be coupled to the second end portion of the first support.

In one or more embodiments, the alignment apparatus may further include a third driver arranged between the second end portion of the first support and the second connector. The third driver may movably and rotatably couple the second end portion of the first support to the second connector, such that the second end portion of the first support may be movable in the X-axis direction and the Z-axis direction and rotatable about the Y-axis direction.

The alignment apparatus and the substrate processing apparatus may precisely or suitably align a deposition mask and a substrate with each other. Therefore, precise (e.g., suitable and/or improved) patterning may be possible by minimizing or reducing a misalignment between the substrate and the mask.

It is to be understood that both the foregoing general description and the following detailed description are example and explanatory and are intended to provide further explanation of present disclosure as claimed.

### BRIEF DESCRIPTION OF THE DRAWINGS

The accompanying drawings, which are included to provide a further understanding of present disclosure and are incorporated in and constitute a part of this specification, illustrate embodiments of present disclosure, and together with the description serve to explain present disclosure.

FIG. 1 is a cross-sectional view illustrating a substrate processing apparatus according to one or more embodiments.

FIGS. 2 and 3 are perspective views illustrating a tray, an alignment apparatus, and a stage according to one or more embodiments.

FIG. 4 is an exploded perspective view illustrating an alignment apparatus according to one or more embodiments.

FIG. 5 is an enlarged exploded perspective view illustrating an area of FIG. 4.

FIG. 6 is an exploded perspective view illustrating some components of FIG. 5.

FIG. 7 is a plan view illustrating a first driver of FIG. 5.

FIG. 8 is a side view illustrating a first driver of FIG. 5.

FIG. 9 is a cross-sectional view taken along the line I-I′ of FIG. 7.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. In the drawings, the sizes and relative sizes of layers and regions may be exaggerated for clarity.

In the disclosure, one or more suitable modifications can be made, one or more suitable forms can be used, and specific embodiments will be illustrated in the drawings and described in more detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third and/or the like may be used herein to describe one or more suitable elements, these elements should not be limited by these terms. These terms are used to distinguish one element from another. Thus, a first element could be termed a second element without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” and/or the like).

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises”, “includes”, “including”, and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Furthermore, spatially relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in one of the drawings is turned over, elements described as being on the “lower” side of other elements would then be oriented on “upper” sides of the other elements. The term “lower,” can therefore, encompasses both (e.g., simultaneously) an orientation of “lower” and “upper,” depending on the particular orientation of the drawing. Similarly, if the device in one of the drawings is turned over, elements described as “below” or “beneath” other elements would then be oriented “above” the other elements. The terms “below” or “beneath” can, therefore, encompass both (e.g., simultaneously) an orientation of above and.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the specification, an X-axis, a Y-axis, and a Z-axis are not limited to three axes on an orthogonal coordinate system, but may be interpreted in a broad sense including the three axes. For example, the X-axis, the Y-axis, and the Z-axis may be normal (e.g., perpendicular) to one another, or may represent different directions that are not normal (e.g., perpendicular) to one another.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

Further, the use of “may” when describing embodiments of the present disclosure refers to “one or more embodiments of the present disclosure”. As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display device, an electronic apparatus including the display device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinafter, embodiments will be described in more detail with reference to the accompanying drawings. The same reference numerals are used for the same components in the drawings, and redundant descriptions of the same components will not be provided.

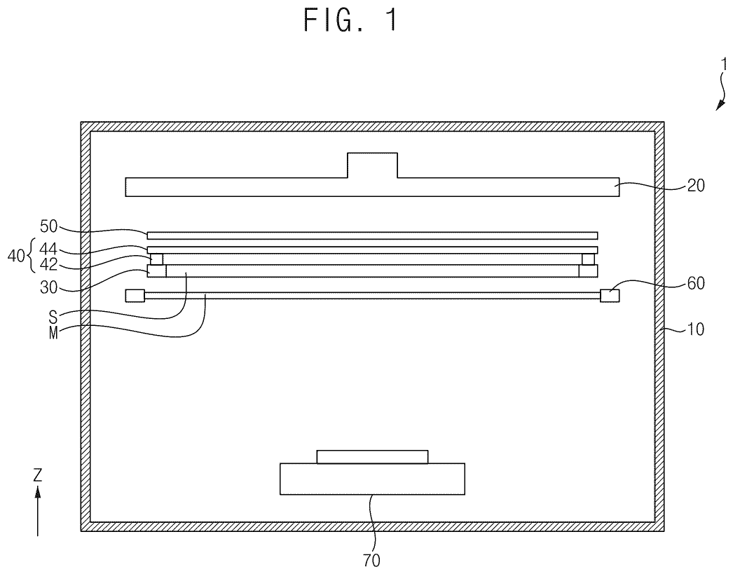

FIG. 1 is a cross-sectional view illustrating a substrate processing apparatus according to one or more embodiments.

Referring to FIG. 1, a substrate processing apparatus 1 according to one or more embodiments may include a chamber 10, a fixing member 20, a tray 30, an alignment apparatus 40, a stage 50, a mask frame 60, and a deposition source 70.

The substrate processing apparatus 1 is an apparatus for processing a substrate S which is a processing target. For example, the processing of the substrate S may be a deposition process in which a deposition material is provided on one surface of the substrate S to form a thin film and/or patterns. However, embodiments are not limited thereto. In some embodiments, the processing of the substrate S may be a dry etching process, a photolithography process, a laser drilling process, and/or the like, and in this case, the deposition source 70 may be variously suitably changed to a UV light source, a laser source, and/or the like.

The chamber 10 may provide an internal space in which the substrate S is processed. The internal space may be in a vacuum state while the substrate S is processed. The chamber 10 may include a bottom surface, a ceiling (e.g., top) surface, and side walls. The bottom surface of the chamber 10 may be substantially parallel to an XY plane. A normal direction of the bottom surface (e.g., a direction normal or substantially perpendicular to the bottom surface) of the chamber 10 may be substantially parallel to the Z-axis direction.

The fixing member 20 may be arranged inside the chamber 10 and may be arranged above (e.g., in the +Z direction) the deposition source 70. The fixing member 20 may be configured to fix (e.g., affix) a mask M and the mask frame 60 on which the mask M is accommodated. In one or more embodiments, the fixing member 20 may be installed on (or fixed onto) the ceiling surface of the chamber 10. The fixing member 20 may include a magnet, a jig, a robot arm, and/or the like for holding the mask M and the mask frame 60. For example, the fixing member 20 may fix (e.g., affix) the mask M and the mask frame 60 with magnetic force, thereby making the mask M be in close contact with the substrate S.

A substrate S may be accommodated (or seated) on the tray 30. The tray 30 may be arranged between the fixing member 20 and the mask frame 60. For example, the substrate S may be a substrate in an intermediate stage of manufacturing a display panel (e.g., in a stage substantially half-way through the manufacturing process of the display panel), but embodiments are not limited thereto.

The alignment apparatus 40 may be arranged on the tray 30 and may be configured to hold (e.g., support) the tray 30. The alignment apparatus 40 may include a holding part 42 and an alignment part 44. The holding part 42 may be coupled to the alignment part 44 and may hold the tray 30.

The stage 50 may be arranged on the alignment apparatus 40 and may be coupled to the alignment part 44 of the alignment apparatus 40. The stage 50 may move the alignment apparatus 40 in the X-axis direction and the Y-axis direction.

The alignment apparatus 40 and the stage 50 may adjust a position and an angle of the tray 30 so that the mask M and the substrate S are aligned (e.g., substantially or suitably aligned) with each other. The tray 30, while held by the alignment apparatus 40, may be moved in each of the X-axis direction, the Y-axis direction, and the Z-axis direction, and/or rotated about each of the X-axis direction, the Y-axis direction, and the Z-axis direction, by the alignment apparatus 40 and the stage 50. For example, the alignment apparatus 40 and the stage 50 may adjust the position and the angle of the tray 30 in six degrees of freedom to more precisely or more suitably align the mask M and the substrate S with each other. The alignment apparatus 40 and the stage 50 will be described in more detail herein below. In other words, the alignment apparatus 40 and the stage 50 adjust the position and angle of the tray 30 to align the mask M and the substrate S. The tray 30 may move and rotate in the X, Y, and Z directions, providing six degrees of freedom (6DOF) for precise alignment. Six degrees of freedom (6DOF) refers to the ways in which a rigid body can move in three-dimensional space, categorized into translational (linear) and rotational movements. Translational movements include surge (movement along the X-axis, forward and backward), sway (movement along the Y-axis, left and right), and heave (movement along the Z-axis, up and down). Rotational movements include yaw (rotation around the Z-axis, turning left and right), pitch (rotation around the Y-axis, tilting forward and backward), and roll (rotation around the X-axis, tilting side to side). These six degrees of freedom allow an object to move freely and rotate in any direction within a three-dimensional space.

The mask M may be accommodated (or seated) on the mask frame 60. The mask frame 60 may be arranged between the tray 30 and the deposition source 70. For example, the mask M may be a deposition mask including a plurality of deposition areas. A plurality of slits may be defined in each of the deposition areas. However, embodiments are not limited thereto. In some embodiments, the mask M may be a photo mask.

The deposition source 70 may spray a deposition material, such as an organic light emitting material, as a vapor. The deposition material sprayed from the deposition source 70 may pass through the slits of the mask M and may be deposited on one surface of the substrate S to form set or predetermined patterns.

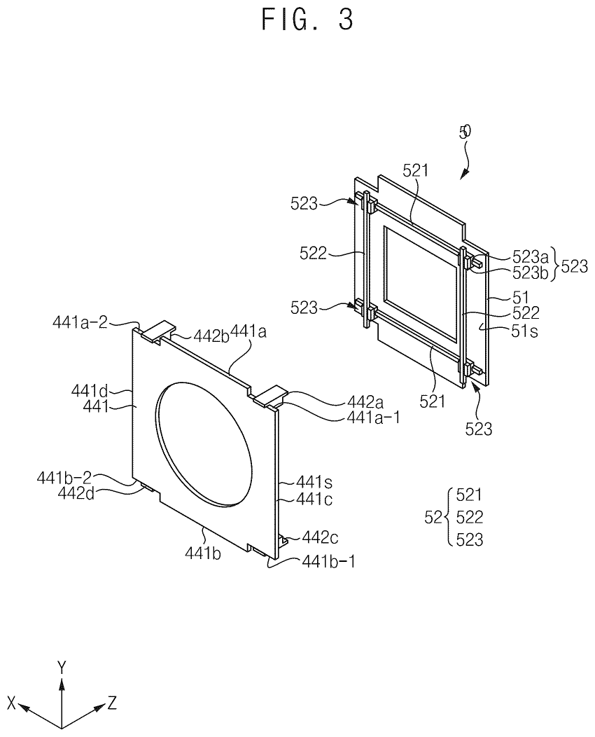

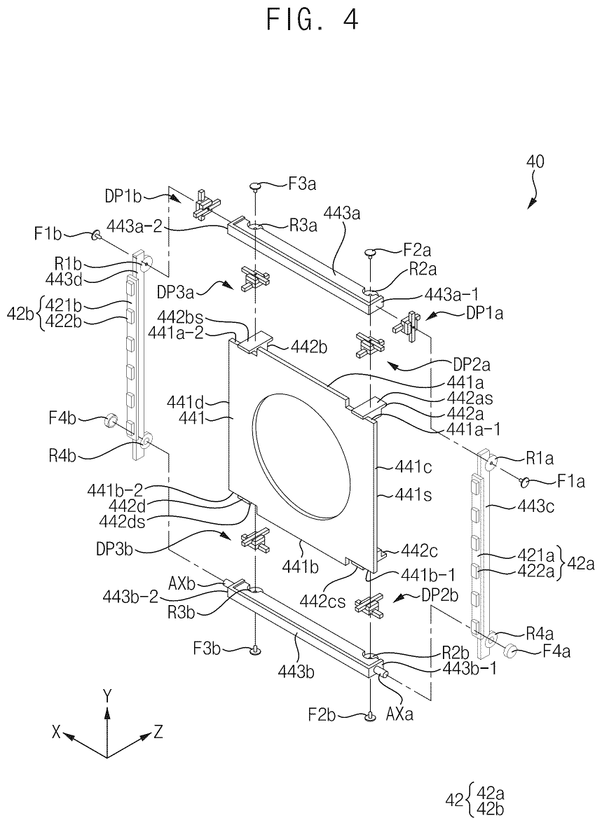

In one or more embodiments, the substrate processing apparatus 1 may further include a measuring device and a controller. The measuring device may measure the alignment state of the substrate S and the mask M. For example, the measuring device may include a vision sensor, a confocal sensor, and/or the like. The controller may control an operation of each of drivers (e.g., a stage driver 52 shown in FIG. 3, and first to sixth drivers DP1a, DP2a, DP3a, DP1b, DP2b, and DP3b shown in FIG. 4) included in the alignment apparatus 40 and the stage 50 based on a measurement value of the alignment state of the substrate S and the mask M measured by the measuring device. Accordingly, the substrate processing apparatus 1 may adjust the position and the angle of the tray 30 in six degrees of freedom (e.g., in a substantially full range of motion) to more precisely or suitably align the mask M and the substrate S with each other. Therefore, precise or improved patterning may be possible by minimizing or reducing a misalignment between the substrate S and the mask M.

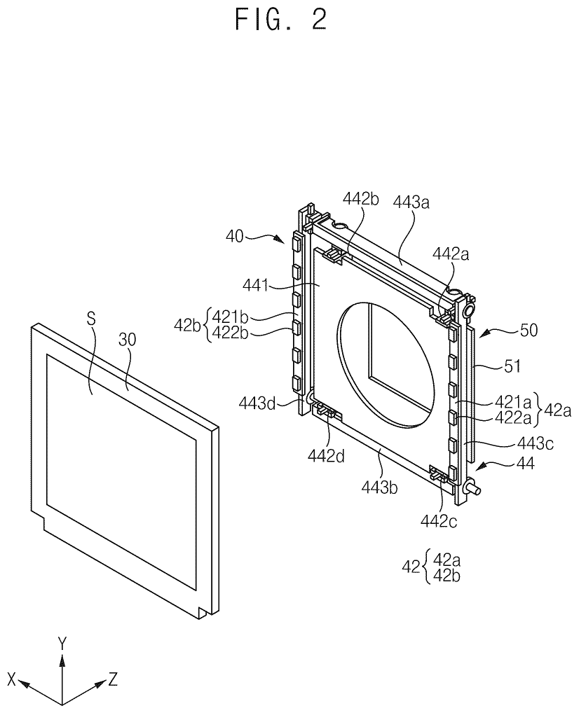

FIGS. 2 and 3 are perspective views illustrating a tray, an alignment apparatus, and a stage according to one or more embodiments.

FIG. 3 illustrates some of the components illustrated in FIG. 2.

Referring to FIGS. 2 and 3, in one or more embodiments, the tray 30 may have a rectangular shape including long sides each extending in the X-axis direction and opposing (e.g., facing or opposite to) each other and short sides each extending in the Y-axis direction and opposing (e.g., facing or opposite to) each other. The substrate S may be accommodated on (e.g., inside) of the tray 30.

In one or more embodiments, the alignment apparatus 40 may include the holding part 42 and the alignment part 44. The holding part 42 may include a first holder 42a and a second holder 42b. The alignment part 44 may include a first plate 441, a first connector 442a, a second connector 442b, a third connector 442c, a fourth connector 442d, a first support 443a, a second support 443b, a third support 443c, and a fourth support 443d.

The first plate 441 may include a first side 441a and a second side 441b each extending in the X-axis direction and opposing (e.g., facing or opposite to) each other, and a third side 441c and a fourth side 441d each extending in the Y-axis direction and opposing (e.g., facing or opposite to) each other. The first side 441a and the second side 441b may be long sides, and the third side 441c and the fourth side 441d may be short sides.

As illustrated in FIG. 3, the first side 441a extending in the X-axis direction may include a center portion, and a first step portion 441a-1 and a second step portion 441a-2 positioned on both (e.g., simultaneously) sides (e.g., opposite ends) of the center portion, respectively. Each of the first step portion 441a-1 and the second step portion 441a-2 may be a recessed portion recessed from the center portion toward the second side 441b (e.g., in the-Y direction).

The second side 441b extending in the X-axis direction may include a center portion, and a first step portion 441b-1 and a second step portion 441b-2 positioned on both (e.g., simultaneously) sides (e.g., opposite ends) of the center portion, respectively. Each of the first step portion 441b-1 and the second step portion 441b-2 may be a recessed portion recessed from the center portion toward the first side 441a (e.g., in the +Y direction).

The first connector 442a and the second connector 442b may be spaced and/or apart (e.g., spaced apart or separated) from each other in the X-axis direction, and each of the first connector 442a and the second connector 442b may be fixedly (not movably and not rotatably, e.g., coupled without an ability to move and/or rotate) coupled to the first side 441a of the first plate 441. The first connector 442a may be fixedly coupled to the first step portion 441a-1 of the first side 441a. The second connector 442b may be fixedly coupled to the second step portion 441a-2 of the first side 441a. In one or more embodiments, each of the first connector 442a and the second connector 442b may be spaced and/or apart (e.g., spaced apart or separated) from the central portion of the first side 441a.

The third connector 442c and the fourth connector 442d may be spaced and/or apart (e.g., spaced apart or separated) from each other in the X-axis direction, and each of the third connector 442c and the fourth connector 442d may be fixedly coupled to the second side 441b of the first plate 441. The third connector 442c may be fixedly coupled to the first step portion 441b-1 of the second side 441b. The fourth connector 442d may be fixedly coupled to the second step portion 441b-2 of the second side 441b. In one or more embodiments, each of the third connector 442c and the fourth connector 442d may be spaced and/or apart (e.g., spaced apart or separated) from the central portion of the second side 441b.

The first support 443a may extend in the X-axis direction. The first support 443a may be coupled to the first connector 442a and the second connector 442b. The first support 443a may include a first end portion and a second end portion opposite to the first end portion. The first end portion of the first support 443a may be coupled to the first connector 442a, and the second end portion of the first support 443a may be coupled to the second connector 442b.

The second support 443b may extend in the X-axis direction. The second support 443b may be coupled to the third connector 442c and the fourth connector 442d. The second support 443b may include a first end portion and a second end portion opposite to the first end portion. The first end portion of the second support 443b may be coupled to the third connector 442c, and the second end portion of the second support 443b may be coupled to the fourth connector 442d.

The third support 443c may extend in the Y-axis direction. The third support 443c may be adjacent to the third side 441c of the first plate 441. The third support 443c may be coupled to the first support 443a and the second support 443b. The third support 443c may include a first end portion and a second end portion opposite to the first end portion. The first end portion of the third support 443c may be coupled to the first end portion of the first support 443a, and the second end portion of the third support 443c may be coupled to the first end portion of the second support 443b.

The fourth support 443d may extend in the Y-axis direction. The fourth support 443d may be adjacent to the fourth side 441d of the first plate 441. The fourth support 443d may be coupled to the first support 443a and the second support 443b. The fourth support 443d may include a first end portion and a second end portion opposite to the first end portion. The first end portion of the fourth support 443d may be coupled to the second end portion of the first support 443a, and the second end portion of the fourth support 443d may be coupled to the second end portion of the second support 443b.

The coupling relationship between the first to fourth supports 443a, 443b, 443c, and 443d will be described in more detail later with reference to FIG. 4.

The first holder 42a may extend in the Y-axis direction. The first holder 42a may be fixedly connected to the third support 443c.

In one or more embodiments, the first holder 42a may include a first extension portion 421a and a first magnet 422a arranged on the first extension portion 421a. The first extension portion 421a may extend in the Y-axis direction and may be fixedly coupled to the third support 443c. The first magnet 422a may be arranged on the first extension portion 421a and may hold (e.g., attach and/or support) the tray 30. The first magnet 422a may include a permanent electromagnet. For example, as illustrated in FIG. 4, a plurality of first magnets 422a may be arranged on the first extension portion 421a to be spaced and/or apart (e.g., spaced apart or separated) from each other in the Y-axis direction. In some embodiments, one first magnet 422a extending (e.g., elongated) in the Y-axis direction may be arranged on the first extension portion 421a. For example, the first holder 42a includes a first extension portion 421a and a first magnet 422a arranged on the first extension portion 421a. The first extension portion 421a extends in the Y-axis direction and is fixedly coupled to the third support 443c. The first magnet 422a, which may be a permanent electromagnet, holds the tray 30. Multiple first magnets 422a may be spaced apart along the Y-axis direction on the first extension portion 421a. Alternatively, a single elongated first magnet 422a may be arranged on the first extension portion 421a.

The second holder 42b may extend in the Y-axis direction. The second holder 42b may be fixedly connected to the fourth support 443d.

In one or more embodiments, the second holder 42b may include a second extension portion 421b and a second magnet 422b arranged on the second extension portion 421b. The second extension portion 421b may extend in the Y-axis direction and may be fixedly coupled to the fourth support 443d. The second magnet 422b may be arranged on the second extension portion 421b and may hold (e.g., attach and/or support) the tray 30. The second magnet 422b may include a permanent electromagnet. For example, as illustrated in FIG. 4, a plurality of second magnets 422b may be arranged on the second extension portion 421b to be spaced and/or apart (e.g., spaced apart or separated) from each other in the Y-axis direction. In some embodiments, one second magnet 422b extending in the Y-axis direction may be arranged on the second extension portion 421b. For example, the second holder 42b includes a second extension portion 421b and a second magnet 422b arranged on the second extension portion 421b. The second extension portion 421b extends in the Y-axis direction and is fixedly coupled to the fourth support 443d. The second magnet 422b, which may be a permanent electromagnet, holds the tray 30. Multiple second magnets 422b may be spaced apart along the Y-axis direction on the second extension portion 421b. Alternatively, a single elongated second magnet 422b may be arranged on the second extension portion 421b.

The first holder 42a and the second holder 42b may be configured to hold the tray 30 together. The first holder 42a and the second holder 42b may hold the short sides of the tray 30, respectively.

In one or more embodiments, the holding part 42 may further include a third holder and a fourth holder that hold the long sides of the tray 30, respectively. The third holder may extend in the X-axis direction and may be fixedly coupled to the first support 443a, and the fourth holder may extend in the X-axis direction and may be fixedly coupled to the second support 443b.

The stage 50 may include a second plate 51 and a stage driver 52. The stage driver 52 may be coupled to the first plate 441 and the second plate 51, and may move the first plate 441 in the X-axis direction and the Y-axis direction with respect to the second plate 51. For example, the first plate 441 may be movably coupled to the second plate 51 (and/or the stage 50), such that the first plate 441 may be movable in the X-axis direction and the Y-axis direction with respect to the second plate 51 (and/or the stage 50).

In one or more embodiments, as illustrated in FIG. 3, the stage driver 52 may include X-axis linear guides 521, Y-axis linear guides 522, and moving blocks 523.

The X-axis linear guides 521 may each extend in the X-axis direction and may be spaced and/or apart (e.g., spaced apart or separated) from each other in the Y-axis direction. The X-axis linear guides 521 may be fixedly coupled to a surface 51s of the second plate 51 opposite to (e.g., facing) the first plate 441.

The Y-axis linear guides 522 may each extend in the Y-axis direction and may be spaced and/or apart (e.g., spaced apart or separated) from each other in the X-axis direction. The Y-axis linear guides 522 may be fixedly coupled to a surface 441s of the first plate 441 opposite to (e.g., facing) the second plate 51.

Each of the moving blocks 523 may be coupled to the X-axis linear guide 521 and the Y-axis linear guide 522. In one or more embodiments, each of the moving blocks 523 may include an X-axis moving block 523a and a Y-axis moving block 523b.

The X-axis moving block 523a may be slidably coupled to the X-axis linear guide 521, such that the X-axis moving block 523a may be slidable in the X-axis direction with respect to the X-axis linear guide 521. The Y-axis moving block 523b may be slidably coupled to the Y-axis linear guide 522, such that the Y-axis moving block 523b may be slidable in the Y-axis direction with respect to the Y-axis linear guide 522. The Y-axis moving block 523b may be fixedly coupled to the X-axis moving block 523a. In one or more embodiments, the stage driver 52 may further include an X-axis motor to slide (e.g., facilitate the sliding of) the X-axis moving block 523a in the X-axis direction and a Y-axis motor to slide (e.g., facilitate the sliding of) the Y-axis moving block 523b in the Y-axis direction.

FIG. 4 is an exploded perspective view illustrating an alignment apparatus according to one or more embodiments.

Referring to FIG. 4, in one or more embodiments, the alignment apparatus 40 (and/or the alignment part 44 of FIG. 2) may further include a first driver DP1a, a second driver DP2a, a third driver DP3a, a fourth driver DP1b, a fifth driver DP2b, and a sixth driver DP3b.

In one or more embodiments, the first driver DP1a may be arranged between the first end portion of the first support 443a and the first end portion of the third support 443c. The first driver DP1a may couple the first end portion of the first support 443a and the first end portion of the third support 443c to each other. For example, the first end portion of the third support 443c may be coupled to the first end portion of the first support 443a through the first driver DP1a.

In one or more embodiments, the first driver DP1a may movably and rotatably couple the first end portion of the third support 443c to the first end portion of the first support 443a, such that the first end portion of the third support 443c may be movable in the Y-axis direction and the Z-axis direction with respect to the first end portion of the first support 443a and rotatable about the X-axis direction with respect to the first end portion of the first support 443a.

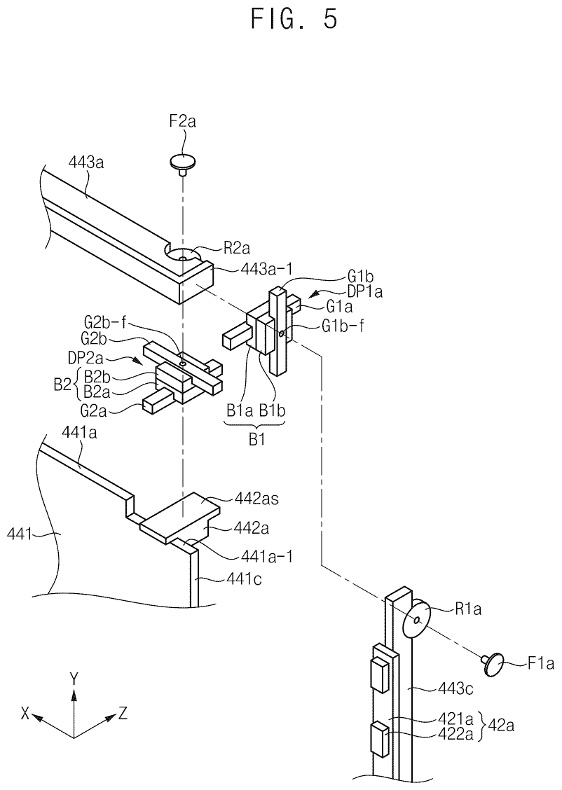

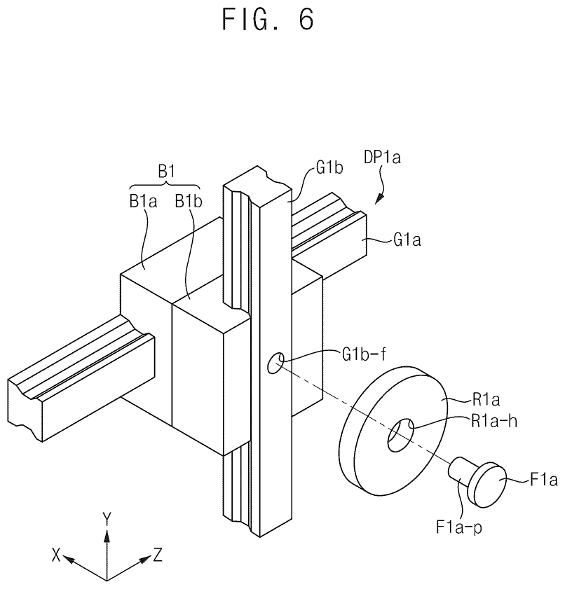

FIG. 5 is an enlarged exploded perspective view illustrating an area of FIG. 4. FIG. 6 is an exploded perspective view illustrating some components of FIG. 5.

FIG. 5 is an enlarged view of an area (upper right area of FIG. 4) near the first driver DP1a and the second driver DP2a of FIG. 4. FIG. 6 illustrates the first driver DP1a, a first rotation coupling portion R1a, and a first fastener Fla of FIG. 5.

Referring further to FIGS. 5 and 6, in one or more embodiments, the first driver DP1a may include a first-first linear guide G1a, a first-second linear guide G1b, and a first moving block B1.

The first-first linear guide G1a may extend in the Z-axis direction. In one or more embodiments, the first-first linear guide G1a may be fixedly coupled to a first side surface 443a-1, opposite to (e.g., facing) the first end portion of the third support 443c, of the first end portion of the first support 443a.

The first-second linear guide G1b may extend in the Y-axis direction. In one or more embodiments, the first-second linear guide G1b may be rotatably coupled to the first end portion of the third support 443c, such that the first-second linear guide G1b may be rotatable about the X-axis direction with respect to the first end portion of the third support 443c.

In one or more embodiments, the first rotation coupling portion R1a may be coupled to the first end portion of the third support 443c. For example, as illustrated in FIG. 5, the first end portion of the third support 443c may define a recess having a shape corresponding to a shape of the first rotation coupling portion R1a, and the first rotation coupling portion R1a may be coupled to the recess of the first end portion of the third support 443c. The first rotation coupling portion R1a may define a through hole R1a-h in the center.

In one or more embodiments, the first-second linear guide G1b may define a fastening groove G1b-f (e.g., G1b-f) that is recessed from a surface, opposite to (e.g., facing) the first end portion of the third support 443c, of the first-second linear guide G1b toward the first support 443a (e.g., in the +X direction).

The first fastener Fla may include a fastening portion F1a-p that protrudes in one direction (e.g., in the +X direction). The fastening portion F1a-p of the first fastener F1a may pass through the through hole R1a-h of the first rotation coupling portion R1a and may be fastened to the fastening groove G1b-f of the first-second linear guide G1b. For example, an outer circumference (e.g., outer circumferential surface) of the fastening portion F1a-p of the first fastener F1a may include a first screw thread; an inner circumference defining the fastening groove G1b-f of the first-second linear guide G1b may include a second screw thread corresponding to the first screw thread; and an inner circumference defining the through hole R1a-h of the first rotation coupling portion R1a may not include (e.g., may exclude) a (e.g., any) screw thread. However, embodiments are not limited thereto.

The first moving block B1 may include a first-first moving block B1a and a first-second moving block B1b. The first-first moving block B1a may be slidably coupled to the first-first linear guide G1a, such that the first-first moving block B1a may be slidable in the Z-axis direction with respect to the first-first linear guide G1a. The first-second moving block B1b may be slidably coupled to the first-second linear guide G1b, such that the first-second moving block B1b may be slidable in the Y-axis direction with respect to the first-second linear guide G1b. The first-second moving block B1b may be fixedly coupled to the first-first moving block B1a. In one or more embodiments, the first driver DP1a may further include a first motor to slide the first-first moving block B1a in the Z-axis direction.

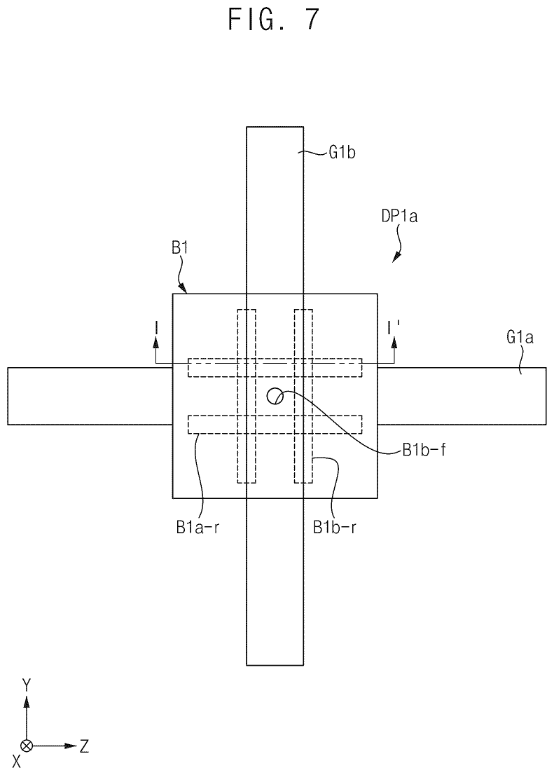

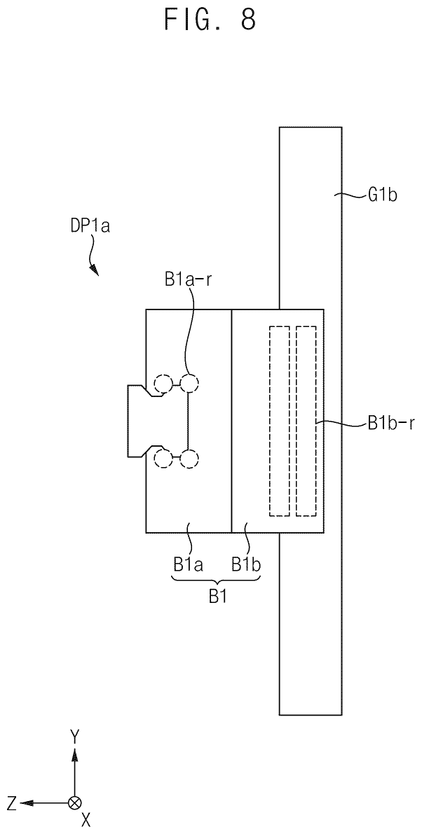

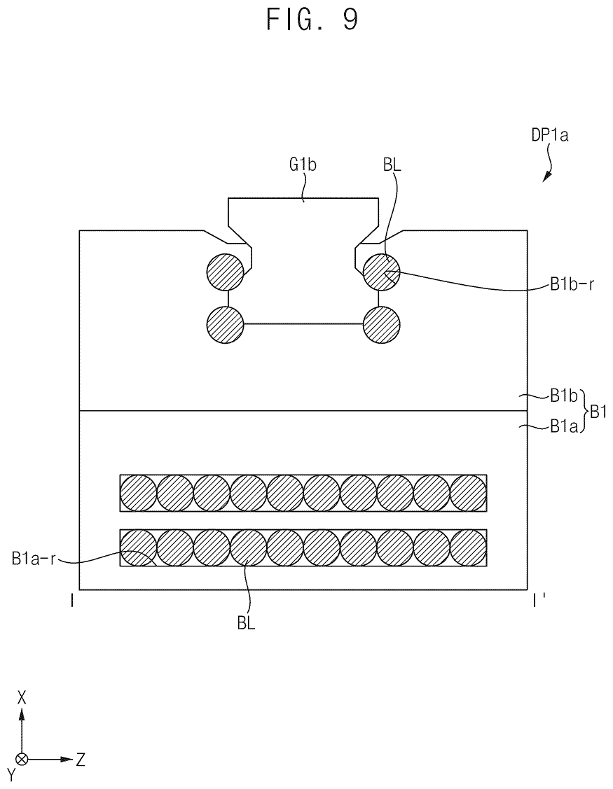

FIG. 7 is a plan view illustrating a first driver of FIG. 5. FIG. 8 is a side view illustrating a first driver of FIG. 5. FIG. 9 is a cross-sectional view taken along the line I-I′ of FIG. 7.

Hereinafter, the first driver DP1a will be described in more detail with reference to FIGS. 7-9.

Referring to FIGS. 7-9, in one or more embodiments, the first-first moving block B1a may define first accommodating grooves B1a-r adjacent to the first-first linear guide G1a. FIGS. 7-9 illustrate that the first-first moving block B1a defines four first accommodating grooves B1a-r, but embodiments are not limited thereto, and the number of first accommodating grooves B1a-r may be variously suitably changed.

In one or more embodiments, each of the first accommodating grooves B1a-r may extend in the Z-axis direction along the first-first linear guide G1a. For example, each of the first accommodating grooves B1a-r may have a cylindrical shape extending in the Z-axis direction. A plurality of balls BL may be arranged in each of the first accommodating grooves B1a-r. The balls BL may be arranged in the Z-axis direction within each of the first accommodating grooves B1a-r.

In one or more embodiments, the first-second moving block B1b may define second accommodating grooves B1b-r adjacent to the first-second linear guide G1b. FIGS. 7-9 illustrate that the first-second moving block B1b defines four second accommodating grooves B1b-r, but embodiments are not limited thereto, and the number of second accommodating grooves B1b-r may be variously suitably changed.

In one or more embodiments, each of the second accommodating grooves B1b-r may extend in the Y-axis direction along the first-second linear guide G1b. For example, each of the second accommodating grooves B1b-r may have a cylindrical shape extending in the Y-axis direction. A plurality of balls BL may be arranged in each of the second accommodating grooves B1b-r. The balls BL may be arranged in the Y-axis direction within each of the second accommodating grooves B1b-r.

Because the plurality of balls BL are arranged in each of the first accommodating grooves B1a-r and the second accommodating grooves B1b-r, load applied to the plurality of balls BL may be evenly (or substantially evenly) distributed. Accordingly, during driving of the first driver DP1a, a durability of the first moving block B1 may be improved.

The description of the first driver DP1a described above with reference to FIGS. 5-9 may be similarly applied to each of the second to sixth drivers DP2a, DP3a, DP1b, DP2b, and DP3b. Therefore, repeated descriptions will not be provided or will be simplified.

Referring again to FIGS. 4 and 5, in one or more embodiments, the second driver DP2a may be arranged between the first end portion of the first support 443a and the first connector 442a. The second driver DP2a may couple the first end portion of the first support 443a and the first connector 442a to each other. For example, the first end portion of the first support 443a may be coupled to the first connector 442a through the second driver DP2a.

In one or more embodiments, the second driver DP2a may movably and rotatably couple the first end portion of the first support 443a to the first connector 442a, such that the first end portion of the first support 443a may be movable in the X-axis direction and the Z-axis direction with respect to the first connector 442a and rotatable about the Y-axis direction with respect to the first connector 442a.

In one or more embodiments, the second driver DP2a may include a second-first linear guide G2a, a second-second linear guide G2b, and a second moving block B2.

The second-first linear guide G2a may extend in the Z-axis direction. In one or more embodiments, the second-first linear guide G2a may be fixedly coupled to a surface 442as, opposite to (e.g., facing) the first end portion of the first support 443a, of the first connector 442a.

The second-second linear guide G2b may extend in the X-axis direction. In one or more embodiments, the second-second linear guide G2b may be rotatably coupled to the first end portion of the first support 443a, such that the second-second linear guide G2b may be rotatable about the Y-axis direction with respect to the first end portion of the first support 443a.

In one or more embodiments, a second rotation coupling portion R2a may be coupled to the first end portion of the first support 443a. For example, as illustrated in

FIG. 5, the first end portion of the first support 443a may define a recess having a shape corresponding to a shape of the second rotation coupling portion R2a, and the second rotation coupling portion R2a may be coupled to the recess of the first end portion of the first support 443a. The second rotation coupling portion R2a may define a through hole in the center.

In one or more embodiments, the second-second linear guide G2b may define a fastening groove G2b-f that is recessed from a surface, opposite to (e.g., facing) the first end portion of the first support 443a, of the second-second linear guide G2b toward the first connector 442a (e.g., in the-Y direction).

A second fastener F2a may include a fastening portion that protrudes in one direction (e.g., in the-Y direction). The fastening portion of the second fastener F2a may pass through the through hole of the second rotation coupling portion R2a and may be fastened to the fastening groove G2b-f of the second-second linear guide G2b. For example, an outer circumference of the fastening portion of the second fastener F2a may include the first screw thread; an inner circumference defining the fastening groove G2b-f of the second-second linear guide G2b may include the second screw thread; and an inner circumference defining the through hole of the second rotation coupling portion R2a may not include (e.g., may exclude) a (e.g., any) screw thread. However, embodiments are not limited thereto.

The second moving block B2 may include a second-first moving block B2a and a second-second moving block B2b. The second-first moving block B2a may be slidably coupled to the second-first linear guide G2a, such that the second-first moving block B2a may be slidable in the Z-axis direction with respect to the second-first linear guide G2a. The second-second moving block B2b may be slidably coupled to the second-second linear guide G2b, such that the second-second moving block B2b may be slidable in the X-axis direction with respect to the second-second linear guide G2b. The second-second moving block B2b may be fixedly coupled to the second-first moving block B2a. In one or more embodiments, the second driver DP2a may further include a second-first motor to slide (e.g., to facilitate the sliding of) the second-first moving block B2a in the Z-axis direction and a second-second motor to slide (e.g., to facilitate the sliding of) the second-second moving block B2b in the X-axis direction.

As illustrated in FIG. 4, in one or more embodiments, the third driver DP3a may be arranged between the second end portion of the first support 443a and the second connector 442b. The third driver DP3a may couple the second end portion of the first support 443a and the second connector 442b to each other. For example, the second end portion of the first support 443a may be coupled to the second connector 442b through the third driver DP3a.

In one or more embodiments, the third driver DP3a may movably and rotatably couple the second end portion of the first support 443a to the second connector 442b, such that the second end portion of the first support 443a may be movable in the X-axis direction and the Z-axis direction with respect to the second connector 442b and rotatable about the Y-axis direction with respect to the second connector 442b.

In one or more embodiments, the third driver DP3a may include a third-first linear guide, a third-second linear guide, and a third moving block.

The third-first linear guide may extend in the Z-axis direction. In one or more embodiments, the third-first linear guide may be fixedly coupled to a surface 442bs, opposite to (e.g., facing) the second end portion of the first support 443a, of the second connector 442b.

The third-second linear guide may extend in the X-axis direction. In one or more embodiments, the third-second linear guide may be rotatably coupled to the second end portion of the first support 443a, such that the third-second linear guide may be rotatable about the Y-axis direction with respect to the second end portion of the first support 443a.

In one or more embodiments, a third rotation coupling portion R3a may be coupled to the second end portion of the first support 443a. For example, as illustrated in FIG. 4, the second end portion of the first support 443a may define a recess having a shape corresponding to a shape of the third rotation coupling portion R3a, and the third rotation coupling portion R3a may be coupled to the recess of the second end portion of the first support 443a. The third rotation coupling portion R3a may define a through hole in the center.

In one or more embodiments, the third-second linear guide may define a fastening groove that is recessed from a surface, opposite to (e.g., facing) the second end portion of the first support 443a, of the third-second linear guide toward the second connector 442b (e.g., in the-Y direction).

A third fastener F3a may include a fastening portion that protrudes in one direction (e.g., in the-Y direction). The fastening portion of the third fastener F3a may pass through the through hole of the third rotation coupling portion R3a and may be fastened to the fastening groove of the third-second linear guide. For example, an outer circumference of the fastening portion of the third fastener F3a may include the first screw thread; an inner circumference defining the fastening groove of the third-second linear guide may include the second screw thread; and an inner circumference defining the through hole of the third rotation coupling portion R3a may not include (e.g., may exclude) a (e.g., any) screw thread. However, embodiments are not limited thereto.

The third moving block may include a third-first moving block and a third-second moving block. The third-first moving block may be slidably coupled to the third-first linear guide, such that the third-first moving block may be slidable in the Z-axis direction with respect to the third-first linear guide. The third-second moving block may be slidably coupled to the third-second linear guide, such that the third-second moving block may be slidable in the X-axis direction with respect to the third-second linear guide. The third-second moving block may be fixedly coupled to the third-first moving block. In one or more embodiments, the third driver DP3a may further include a third motor to slide (e.g., to facilitate the sliding of) the third-first moving block in the Z-axis direction.

In one or more embodiments, the fourth driver DP1b may be arranged between the second end portion of the first support 443a and the first end portion of the fourth support 443d. The fourth driver DP1b may couple the second end portion of the first support 443a and the first end portion of the fourth support 443d to each other. For example, the first end portion of the fourth support 443d may be coupled to the second end portion of the first support 443a through the fourth driver DP1b.

In one or more embodiments, the fourth driver DP1b may movably and rotatably couple the first end portion of the fourth support 443d to the second end portion of the first support 443a, such that the first end portion of the fourth support 443d may be movable in the Y-axis direction and the Z-axis direction with respect to the second end portion of the first support 443a and rotatable about the X-axis direction with respect to the second end portion of the first support 443a.

In one or more embodiments, the fourth driver DP1b may include a fourth-first linear guide, a fourth-second linear guide, and a fourth moving block.

The fourth-first linear guide may extend in the Z-axis direction. In one or more embodiments, the fourth-first linear guide may be fixedly coupled to a second side surface 443a-2, opposite to (e.g., facing) the first end portion of the fourth support 443d, of the second end portion of the first support 443a.

The fourth-second linear guide may extend in the Y-axis direction. In one or more embodiments, the fourth-second linear guide may be rotatably coupled to the first end portion of the fourth support 443d, such that the fourth-second linear guide may be rotatable about the X-axis direction with respect to the first end portion of the fourth support 443d.

In one or more embodiments, a fourth rotation coupling portion R1b may be coupled to the first end portion of the fourth support 443d. For example, as illustrated in FIG. 4, the first end portion of the fourth support 443d may define a recess having a shape corresponding to a shape of the fourth rotation coupling portion R1b, and the fourth rotation coupling portion R1b may be coupled to the recess of the first end portion of the fourth support 443d. The fourth rotation coupling portion R1b may define a through hole in the center.

In one or more embodiments, the fourth-second linear guide may define a fastening groove that is recessed from a surface, opposite to (e.g., facing) the first end portion of the fourth support 443d, of the fourth-second linear guide toward the first support 443a (e.g., in the-X direction).

A fourth fastener F1b may include a fastening portion that protrudes in one direction (e.g., in the-X direction). The fastening portion of the fourth fastener F1b may pass through the through hole of the fourth rotation coupling portion R1b and may be fastened to the fastening groove of the fourth-second linear guide. For example, an outer circumference of the fastening portion of the fourth fastener F1b may include the first screw thread; an inner circumference defining the fastening groove of the fourth-second linear guide may include the second screw thread; and an inner circumference defining the through hole of the fourth rotation coupling portion R1b may not include (e.g., may exclude) a (e.g., any) screw thread. However, embodiments are not limited thereto.

The fourth moving block may include a fourth-first moving block and a fourth-second moving block. The fourth-first moving block may be slidably coupled to the fourth-first linear guide, such that the fourth-first moving block may be slidable in the Z-axis direction with respect to the fourth-first linear guide. The fourth-second moving block may be slidably coupled to the fourth-second linear guide, such that the fourth-second moving block may be slidable in the Y-axis direction with respect to the fourth-second linear guide. The fourth-second moving block may be fixedly coupled to the fourth-first moving block. In one or more embodiments, the fourth driver DP1b may further include a fourth motor to slide (e.g., to facilitate the sliding of) the fourth-first moving block in the Z-axis direction.

In one or more embodiments, the fifth driver DP2b may be arranged between the first end portion of the second support 443b and the third connector 442c. The fifth driver DP2b may couple the first end portion of the second support 443b and the third connector 442c to each other. For example, the first end portion of the second support 443b may be coupled to the third connector 442c through the fifth driver DP2b.

In one or more embodiments, the fifth driver DP2b may movably and rotatably couple the first end portion of the second support 443b to the third connector 442c, such that the first end portion of the second support 443b may be movable in the X-axis direction and the Z-axis direction with respect to the third connector 442c and rotatable about the Y-axis direction with respect to the third connector 442c.

In one or more embodiments, the fifth driver DP2b may include a fifth-first linear guide, a fifth-second linear guide, and a fifth moving block.

The fifth-first linear guide may extend in the Z-axis direction. In one or more embodiments, the fifth-first linear guide may be fixedly coupled to a surface 442cs, opposite to (e.g., facing) the first end portion of the second support 443b, of the third connector 442c.

The fifth-second linear guide may extend in the X-axis direction. In one or more embodiments, the fifth-second linear guide may be rotatably coupled to the first end portion of the second support 443b, such that the fifth-second linear guide may be rotatable about the Y-axis direction with respect to the first end portion of the second support 443b.

In one or more embodiments, a fifth rotation coupling portion R2b may be coupled to the first end portion of the second support 443b. For example, as illustrated in FIG. 4, the first end portion of the second support 443b may define a recess having a shape corresponding to a shape of the fifth rotation coupling portion R2b, and the fifth rotation coupling portion R2b may be coupled to the recess of the first end portion of the second support 443b. The fifth rotation coupling portion R2b may define a through hole in the center.

In one or more embodiments, the fifth-second linear guide may define a fastening groove that is recessed from a surface, opposite to (e.g., facing) the first end portion of the second support 443b, of the fifth-second linear guide toward the third connector 442c (e.g., in the +Y direction).

A fifth fastener F2b may include a fastening portion that protrudes in one direction (e.g., in the +Y direction). The fastening portion of the fifth fastener F2b may pass through the through hole of the fifth rotation coupling portion R2b and may be fastened to the fastening groove of the fifth-second linear guide. For example, an outer circumference of the fastening portion of the fifth fastener F2b may include the first screw thread; an inner circumference defining the fastening groove of the fifth-second linear guide may include the second screw thread; and an inner circumference defining the through hole of the fifth rotation coupling portion R2b may not include (e.g., may exclude) a (e.g., any) screw thread. However, embodiments are not limited thereto.

The fifth moving block may include a fifth-first moving block and a fifth-second moving block. The fifth-first moving block may be slidably coupled to the fifth-first linear guide, such that the fifth-first moving block may be slidable in the Z-axis direction with respect to the fifth-first linear guide. The fifth-second moving block may be slidably coupled to the fifth-second linear guide, such that the fifth-second moving block may be slidable in the X-axis direction with respect to the fifth-second linear guide. The fifth-second moving block may be fixedly coupled to the fifth-first moving block. In one or more embodiments, the fifth driver DP2b may further include a fifth-first motor to slide (e.g., to facilitate the sliding of) the fifth-first moving block in the Z-axis direction and a fifth-second motor to slide (e.g., to facilitate the sliding of) the fifth-second moving block B2b in the X-axis direction.

In one or more embodiments, the sixth driver DP3b may be arranged between the second end portion of the second support 443b and the fourth connector 442d. The sixth driver DP3b may couple the second end portion of the second support 443b and the fourth connector 442d to each other. For example, the second end portion of the second support 443b may be coupled to the fourth connector 442d through the sixth driver DP3b.

In one or more embodiments, the sixth driver DP3b may movably and rotatably couple the second end portion of the second support 443b to the fourth connector 442d, such that the second end portion of the second support 443b may be movable in the X-axis direction and the Z-axis direction with respect to the fourth connector 442d and rotatable about the Y-axis direction with respect to the fourth connector 442d.

In one or more embodiments, the sixth driver DP3b may include a sixth-first linear guide, a sixth-second linear guide, and a sixth moving block.

The sixth-first linear guide may extend in the Z-axis direction. In one or more embodiments, the sixth-first linear guide may be fixedly coupled to a surface 442ds, opposite to (e.g., facing) the second end portion of the second support 443b, of the fourth connector 442d.

The sixth-second linear guide may extend in the X-axis direction. In one or more embodiments, the sixth-second linear guide may be rotatably coupled to the second end portion of the second support 443b, such that the sixth-second linear guide may be rotatable about the Y-axis direction with respect to the second end portion of the second support 443b.

In one or more embodiments, a sixth rotation coupling portion R3b may be coupled to the second end portion of the second support 443b. For example, as illustrated in FIG. 4, the second end portion of the second support 443b may define a recess having a shape corresponding to a shape of the sixth rotation coupling portion

R3b, and the sixth rotation coupling portion R3b may be coupled to the recess of the second end portion of the second support 443b. The sixth rotation coupling portion R3b may define a through hole in the center.

In one or more embodiments, the sixth-second linear guide may define a fastening groove that is recessed from a surface, opposite to (e.g., facing) the second end portion of the second support 443b, of the sixth-second linear guide toward the fourth connector 442d (e.g., in the +Y direction).

A sixth fastener F3b may include a fastening portion that protrudes in one direction (e.g., in the +Y direction). The fastening portion of the sixth fastener F3b may pass through the through hole of the sixth rotation coupling portion R3b and may be fastened to the fastening groove of the sixth-second linear guide. For example, an outer circumference of the fastening portion of the sixth fastener F3b may include the first screw thread an inner circumference defining the fastening groove of the sixth-second linear guide may include the second screw thread; and an inner circumference defining the through hole of the sixth rotation coupling portion R3b may not include (e.g., may exclude) a (e.g., any) screw thread. However, embodiments are not limited thereto.

The sixth moving block may include a sixth-first moving block and a sixth-second moving block. The sixth-first moving block may be slidably coupled to the sixth-first linear guide, such that the sixth-first moving block may be slidable in the Z-axis direction with respect to the sixth-first linear guide. The sixth-second moving block may be slidably coupled to the sixth-second linear guide, such that the sixth-second moving block may be slidable in the X-axis direction with respect to the sixth-second linear guide. The sixth-second moving block may be fixedly coupled to the sixth-first moving block. In one or more embodiments, the sixth driver DP3b may further include a sixth motor to slide (e.g., to facilitate the sliding of) the sixth-first moving block in the Z-axis direction.

In one or more embodiments, the second end portion of the third support 443c may be rotatably coupled to the first end portion of the second support 443b, such that the second end portion of the third support 443c may be rotatable about the X-axis direction with respect to the first end portion of the second support 443b.

In one or more embodiments, the first end portion of the second support 443b may include a first protrusion AXa that protrudes toward the third support 443c (e.g., in the-X direction). The first protrusion AXa may protrude in the-X direction from a first side surface 443b-1, opposite to (e.g., facing) the second end portion of the third support 443c, of the first end portion of the second support 443b.

A seventh rotation coupling portion R4a may be coupled to the second end portion of the third support 443c. For example, as illustrated in FIG. 4, the second end portion of the third support 443c may define a recess having a shape corresponding to a shape of the seventh rotation coupling portion R4a, and the seventh rotation coupling portion R4a may be coupled to the recess of the second end portion of the third support 443c. The seventh rotation coupling portion R4a may define a through hole in the center.

The first protrusion AXa may pass through the through hole of the seventh rotation coupling portion R4a and may be fastened to a seventh fastener F4a. For example, an outer circumference of the first protrusion AXa may include a third screw thread; an inner circumference of the seventh fastener F4a may include a fourth screw thread corresponding to the third screw thread; and an inner circumference defining the through hole of the seventh rotation coupling portion R4a may not include (e.g., may exclude) a (e.g., any) screw thread. However, embodiments are not limited thereto.

In one or more embodiments, the second end portion of the fourth support 443d may be rotatably coupled to the second end portion of the second support 443b, such that the second end portion of the fourth support 443d may be rotatable about the X-axis direction with respect to the second end portion of the second support 443b.

In one or more embodiments, the second end portion of the second support 443b may include a second protrusion AXb that protrudes toward the fourth support 443d (e.g., in the +X direction). The second protrusion AXb may protrude in the +X direction from a second side surface 443b-2, opposite to (e.g., facing) the second end portion of the fourth support 443d, of the second end portion of the second support 443b.

An eighth rotation coupling portion R4b may be coupled to the second end portion of the fourth support 443d. For example, as illustrated in FIG. 4, the second end portion of the fourth support 443d may define a recess having a shape corresponding to a shape of the eighth rotation coupling portion R4b, and the eighth rotation coupling portion R4b may be coupled to the recess of the second end portion of the fourth support 443d. The eighth rotation coupling portion R4b may define a through hole in the center.

The second protrusion AXb may pass through the through hole of the eighth rotation coupling portion R4b and may be fastened to an eighth fastener F4b. For example, an outer circumference of the second protrusion AXb may include the third screw thread; an inner circumference of the eighth fastener F4b may include the fourth screw thread; and an inner circumference defining the through hole of the eighth rotation coupling portion R4b may not include (e.g., may exclude) a (e.g., any) screw thread. However, embodiments are not limited thereto.

As used herein, “outer circumference” may refer to an outer circumferential surface of the corresponding part, and “inner circumference” may refer to an inner circumferential surface of the corresponding part.

According to one or more embodiments, the substrate processing apparatus 1 may suitably adjust the position and the angle of the tray 30 on which the substrate S is accommodated in six degrees of freedom. Therefore, the substrate processing apparatus 1 may more precisely align the mask M and the substrate S with each other.

Although embodiments and implementations have been described herein, one or more embodiments and modifications will be apparent from this description. Accordingly, present disclosure is not limited to such embodiments, but rather to the broader scope of the appended claims and one or more suitable obvious modifications and equivalent arrangements as would be apparent to a person of ordinary skill in the art.

What is claimed is:

1. An alignment apparatus comprising:
a plate comprising first to fourth sides, the first and second sides each extending in an X-axis direction and opposite to each other, the third and fourth sides each extending in a Y-axis direction and opposite to each other;
a first connector and a second connector spaced from each other in the X-axis direction, each of the first connector and the second connector being fixedly coupled to the first side of the plate;
a third connector and a fourth connector spaced from each other in the X-axis direction, each of the third connector and the fourth connector being fixedly coupled to the second side of the plate;
a first support extending in the X-axis direction and comprising a first end portion and a second end portion, the first end portion of the first support being coupled to the first connector, the second end portion of the first support being coupled to the second connector;
a second support extending in the X-axis direction and comprising a first end portion and a second end portion, the first end portion of the second support being coupled to the third connector, the second end portion of the second support being coupled to the fourth connector;
a third support extending in the Y-axis direction, adjacent to the third side of the plate, and comprising a first end portion and a second end portion, the first end portion of the third support being coupled to the first end portion of the first support;
a first driver between the first end portion of the first support and the first end portion of the third support, the first driver movably and rotatably coupling the first end portion of the third support to the first end portion of the first support, the first end portion of the third support being movable in the Y-axis direction and a Z-axis direction and rotatable about the X-axis direction; and
1 a first holder fixedly coupled to the third support and configured to hold a tray on which a substrate is accommodated.

2. The alignment apparatus of claim 1, wherein the first driver comprises:
a first-first linear guide extending in the Z-axis direction;
a first-second linear guide extending in the Y-axis direction;
a first-first moving block slidably coupled to the first-first linear guide, the first-first moving block being slidable in the Z-axis direction; and
a first-second moving block slidably coupled to the first-second linear guide, the first-second moving block being slidable in the Y-axis direction, the first-second moving block being fixedly coupled to the first-first moving block.

3. The alignment apparatus of claim 2, wherein
the first-first moving block defines a first accommodating groove adjacent to the first-first linear guide and having a cylindrical shape extending in the Z-axis direction, and
a plurality of balls in the first accommodating groove.

4. The alignment apparatus of claim 2, wherein
the first-second moving block defines a second accommodating groove adjacent to the first-second linear guide and having a cylindrical shape extending in the Y-axis direction, and
a plurality of balls in the second accommodating groove.

5. The alignment apparatus of claim 2, wherein the first driver further comprises:
a first motor to slide the first-first moving block in the Z-axis direction.

6. The alignment apparatus of claim 2, wherein the first-first linear guide is fixedly coupled to a side surface of the first end portion of the first support opposite to the first end portion of the third support.

7. The alignment apparatus of claim 2, wherein the first-second linear guide is rotatably coupled to the first end portion of the third support, and the first-second linear guide is rotatable about the X-axis direction.

8. The alignment apparatus of claim 1, further comprises:
a second driver between the first end portion of the first support and the first connector, the second driver movably and rotatably coupling the first end portion of the first support to the first connector, the first end portion of the first support being movable in the X-axis direction and the Z-axis direction and rotatable about the Y-axis direction.

9. The alignment apparatus of claim 8, wherein the second driver comprises:
a second-first linear guide extending in the Z-axis direction;
a second-second linear guide extending in the X-axis direction;
a second-first moving block slidably coupled to the second-first linear guide, the second-first moving block being slidable in the Z-axis direction; and
a second-second moving block slidably coupled to the second-second linear guide, the second-second moving block being slidable in the X-axis direction, the second-second moving block being fixedly coupled to the second-first moving block.

10. The alignment apparatus of claim 9, wherein the first driver further comprises:
a second-first motor to slide the second-first moving block in the Z-axis direction; and
a second-second motor to slide the second-second moving block in the X-axis direction.

11. The alignment apparatus of claim 9, wherein the second-first linear guide is fixedly coupled to a surface of the first connector opposite to the first end portion of the first support.

12. The alignment apparatus of claim 9, wherein the second-second linear guide is rotatably coupled to the first end portion of the first support, and the second-second linear guide is rotatable about the Y-axis direction.

13. The alignment apparatus of claim 1, wherein the second end portion of the third support is rotatably coupled to the first end portion of the second support, and the second end portion of the third support is rotatable about the X-axis direction.

14. The alignment apparatus of claim 1, further comprises:
a fourth support extending in the Y-axis direction, adjacent to the fourth side of the plate, and comprising a first end portion and a second end portion, the first end portion of the fourth support being coupled to the second end portion of the first support; and
a second holder fixedly coupled to the fourth support and configured to hold the tray.

15. The alignment apparatus of claim 14, further comprises:
a third driver between the second end portion of the first support and the second connector, the third driver movably and rotatably coupling the second end portion of the first support to the second connector, the second end portion of the first support being movable in the X-axis direction and the Z-axis direction and rotatable about the Y-axis direction.

16. The alignment apparatus of claim 14, wherein the second end portion of the fourth support is rotatably coupled to the second end portion of the second support, and the second end portion of the fourth support is rotatable about the X-axis direction.

17. A substrate processing apparatus comprising:
a mask frame on which a mask is configured to be accommodated;
a tray on the mask frame and on which a substrate is configured to be accommodated;
an alignment apparatus on the tray and configured to hold the tray; and
a stage on the alignment apparatus,
wherein the alignment apparatus comprises:
a plate comprising first to fourth sides and movably coupled to the stage, the first and second sides each extending in an X-axis direction and opposite to each other, the third and fourth sides each extending in a Y-axis direction and opposite to each other, the plate being movable in the X-axis direction and the Y-axis direction;
a first connector and a second connector spaced from each other in the X-axis direction, each of the first connector and the second connector being fixedly coupled to the first side of the plate;
a third connector and a fourth connector spaced from each other in the X-axis direction, each of the third connector and the fourth connector being fixedly coupled to the second side of the plate;
a first support extending in the X-axis direction and comprising a first end portion and a second end portion, the first end portion of the first support being coupled to the first connector, the second end portion of the first support being coupled to the second connector;
a second support extending in the X-axis direction and comprising a first end portion and a second end portion, the first end portion of the second support being coupled to the third connector, the second end portion of the second support being coupled to the fourth connector;
a third support extending in the Y-axis direction, adjacent to the third side of the plate, and comprising a first end portion and a second end portion, the first end portion of the third support being coupled to the first end portion of the first support;
a first driver between the first end portion of the first support and the first end portion of the third support, the first driver movably and rotatably coupling the first end portion of the third support to the first end portion of the first support, the first end portion of the third support being movable in the Y-axis direction and a Z-axis direction and rotatable about the X-axis direction; and
a first holder fixedly coupled to the third support and configured to hold the tray.

18. The substrate processing apparatus of claim 17, wherein the alignment apparatus further comprises:
a second driver between the first end portion of the first support and the first connector, the second driver movably and rotatably coupling the first end portion of the first support to the first connector, the first end portion of the first support being movable in the X-axis direction and the Z-axis direction and rotatable about the Y-axis direction.

19. The substrate processing apparatus of claim 17, wherein the alignment apparatus further comprises:
a fourth support extending in the Y-axis direction, adjacent to the fourth side of the plate, and comprising a first end portion and a second end portion, the first end portion of the fourth support being coupled to the second end portion of the first support;
a second holder fixedly coupled to the fourth support and configured to hold the tray; and
a third driver between the second end portion of the first support and the second connector, the third driver movably and rotatably coupling the second end portion of the first support to the second connector, the second end portion of the first support being movable in the X-axis direction and the Z-axis direction and rotatable about the Y-axis direction.

20. An electronic apparatus comprising:
a display device formed by an alignment apparatus,
wherein the alignment apparatus comprises:
a plate comprising first to fourth sides and movably coupled to the stage, the first and second sides each extending in an X-axis direction and opposite to each other, the third and fourth sides each extending in a Y-axis direction and opposite to each other, the plate being movable in the X-axis direction and the Y-axis direction;
a first connector and a second connector spaced from each other in the X-axis direction, each of the first connector and the second connector being fixedly coupled to the first side of the plate;
a third connector and a fourth connector spaced from each other in the X-axis direction, each of the third connector and the fourth connector being fixedly coupled to the second side of the plate;
a first support extending in the X-axis direction and comprising a first end portion and a second end portion, the first end portion of the first support being coupled to the first connector, the second end portion of the first support being coupled to the second connector;
a second support extending in the X-axis direction and comprising a first end portion and a second end portion, the first end portion of the second support being coupled to the third connector, the second end portion of the second support being coupled to the fourth connector;
a third support extending in the Y-axis direction, adjacent to the third side of the plate, and comprising a first end portion and a second end portion, the first end portion of the third support being coupled to the first end portion of the first support;
a first driver between the first end portion of the first support and the first end portion of the third support, the first driver movably and rotatably coupling the first end portion of the third support to the first end portion of the first support, the first end portion of the third support being movable in the Y-axis direction and a Z-axis direction and rotatable about the X-axis direction; and
a first holder fixedly coupled to the third support and configured to hold the tray.
